(19) United States
(12) Patent Application Publication
(10) Pub. No.: US 2009/0113726 A1
(43) Pub. Date: May 7, 2009

(54) METHOD FOR OBTAINING A HARD SURFACE AT THE NANOSCALE

(76) Inventors: Cedric DUCROS, BEVENAIS (FR); Frederic SANCHETTE, MONTFERRAT (FR); Vincent SANZONE, CHAPAREILLAN (FR)

Correspondence Address: SUMMA, ADDITON & ASHE, P.A., 11610 NORTH COMMUNITY HOUSE ROAD, SUITE 200, CHARLOTTE, NC, 28277, US

(21) Appl. No.: 12/237,441

(22) Filed: Sep. 25, 2008

(30) Foreign Application Priority Data
Sep. 28, 2007 (FR) 0706816

(51) Int. Cl. B26B 21/54; C23C 14/35

(52) U.S. Cl. 30/346.53; 204/192.16; 30/346.5

(57) ABSTRACT

The invention relates to a method for forming a thin, high hardness coating and devices comprising it.

The method of the invention consists in depositing, by magnetron cathode sputtering, a titanium film on at least one surface of a substrate under a partial pressure of argon of 1 Pa, then in depositing, by magnetron cathode sputtering, a titanium nitride film, onto the film obtained by introducing nitrogen into the cathodic sputtering chamber while maintaining a partial pressure of 1 Pa, and in depositing a film of a composite nanostructured material based on titanium, zirconium, boron and nitrogen onto the film obtained by magnetron cathode sputtering in active co-sputtering mode.

The method of the invention can be applied in many fields, and in particular in the mechanical field in order to improve the surface hardness of mechanical components.

The invention relates to a method for forming a coating of a thickness of less than or equal to 200 nm and with a hardness greater than or equal to 20 GPa.

It also relates to devices comprising a coating obtained by this method.

Ultra-hard thin films are widely used in many fields in order to protect certain assemblies or parts against abrasive wear. These parts may be micro-objects (MEMs), but also objects where there is a desire to preserve geometrical aspects, such as for example the radius of a cutting edge of a razor blade.

Coatings of the metal-BN type are widely used in the mechanical field in order to improve the surface hardness of mechanical components.

The most commonly used metal-BN coatings are TiBN, ZrBN and TiAlBN.

In particular, coatings with nanocomposite structure have been much studied with the aim of obtaining very high hardness levels.

The method of magnetron cathode sputtering in reactive co-sputtering mode is well known in the field of fabricating hard thin films.

This method allows films of extremely precise composition to be obtained with a low surface roughness. These films have thicknesses greater than 2 micrometres to attain film hardnesses of 30 GPa, but it does not allow hard films to be obtained with a sufficient level of adherence to the substrate, in particular for applications in which the coated parts are strongly thermo-mechanically stressed.

The cathodic arc evaporation method is also known for developing hard films, but to date it has not allowed hard films less than 2 micrometres thick to be obtained.

Thus for the formation of hard films for applications in which the coated part is strongly thermo-mechanically stressed, the cathodic arc evaporation method is currently used because it allows very high levels of adherence to the hard film on the coated part due to the very high ionization rate of the vapour generated by the cathodic arc evaporation technique, which is around 90% while this rate is only a few percent, 10% at best, for magnetron cathode sputtering. In addition, in the cathodic arc evaporation method, the bombardment of the film being grown is encouraged through this high ionization rate by applying a negative bias voltage to the parts to be coated.

However, this cathodic arc evaporation method generates a high surface roughness which does not allow hard films to be obtained that do not modify the geometry of the coated parts for thicknesses lower than 2 micrometres.

In particular, the aspect of surface roughness is important because for total coating thicknesses of around 200 nm a surface roughness of the same order is unacceptable for a mechanical application.

The invention aims to remedy the drawbacks of the methods of the prior art by proposing a method for obtaining hard films of a material with a nanocomposite structure by magnetron cathode sputtering, which enables hard films having a thickness of less than or equal to 200 nm and a hardness greater than or equal to 20 GPa to be obtained, with a low surface roughness and a high adherence level.

To this end, the invention proposes a method for forming, on a substrate, a coating with a thickness less than or equal to 200 nm and a hardness greater than or equal to 20 GPa, and made of a material with a nanocomposite structure based on titanium, zirconium, boron and nitrogen, which comprises the following steps:
a) deposition, by magnetron cathode sputtering, of a titanium film on at least one surface of said substrate under a partial pressure of argon of 1 Pa;
b) deposition, by magnetron cathode sputtering, of a titanium nitride film, onto the film obtained in step a) by introducing nitrogen into the cathodic sputtering chamber while maintaining a partial pressure of 1 Pa;
c) deposition of a film of a composite nanostructured material based on titanium, Zr, boron and nitrogen onto the film obtained in step b) by magnetron cathode sputtering in active co-sputtering mode by applying a power X to a target source of titanium and a power Y to a target source of ZrB₂, the ratio X/Y being between 3/5 and 5/3 inclusive, and simultaneous injection of a gas mixture composed of argon and nitrogen, the nitrogen representing at least 10% by volume of the total volume of the gas mixture, while maintaining a partial pressure of 1 Pa and applying a bias voltage of −300 V in the cathodic sputtering chamber.

Preferably, in the method of the invention, in step c), the percentage of nitrogen introduced into the magnetron cathodic sputtering chamber is 10% by volume in relation to the total volume of the gas mixture introduced.

Again preferably, in the method of the invention the ratio of the powers X/Y applied to the targets in step c) is 1.

The invention also encompasses devices comprising a coating obtained by the method of the invention, and more particularly razor blades. It is to be noted that for razor blades, it is not compulsory to coat the entire razor blade but that only the edges of the razor blade can be coated.

The invention will be better understood and other features and advantages thereof will appear more clearly on reading the explanatory description that follows and which is provided with reference to the figures in which:

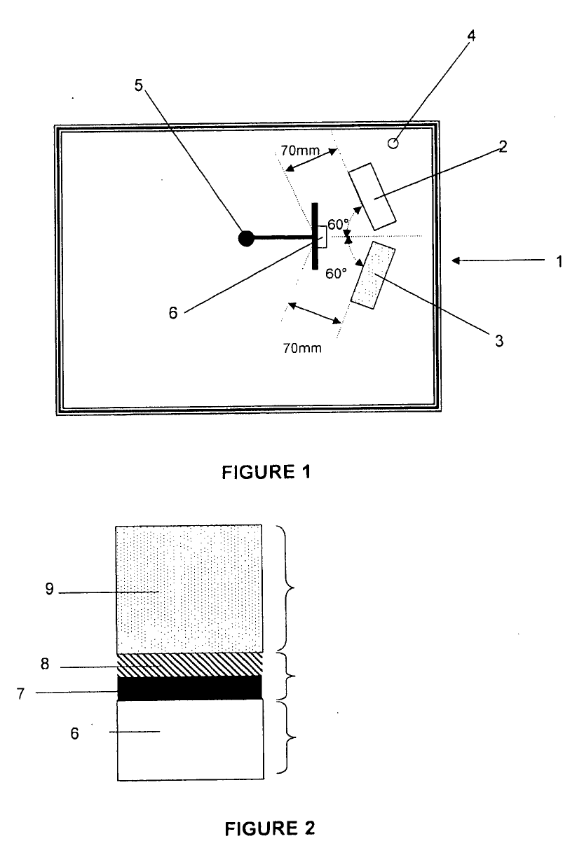

FIG. 1 schematically represents a magnetron cathode sputtering device in active co-sputtering mode;

FIG. 2 schematically represents a section of a part, one surface of which is coated with the coating of the invention;

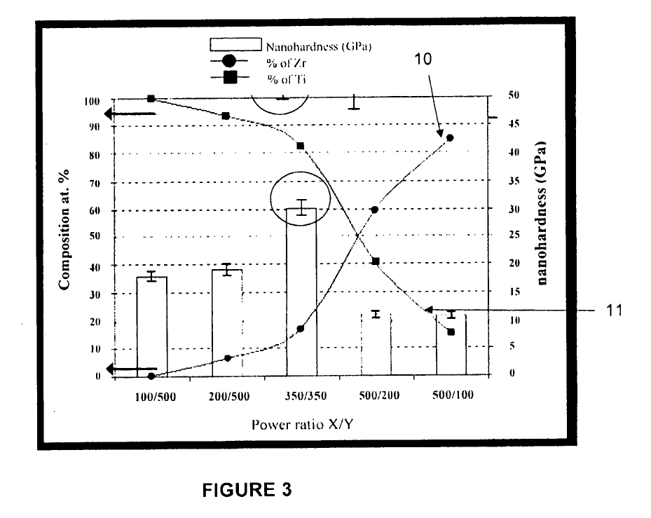

FIG. 3 represents the influence of the power ratio X/Y on the composition in atomic percentage and the hardness of the final film of the coating of the invention;

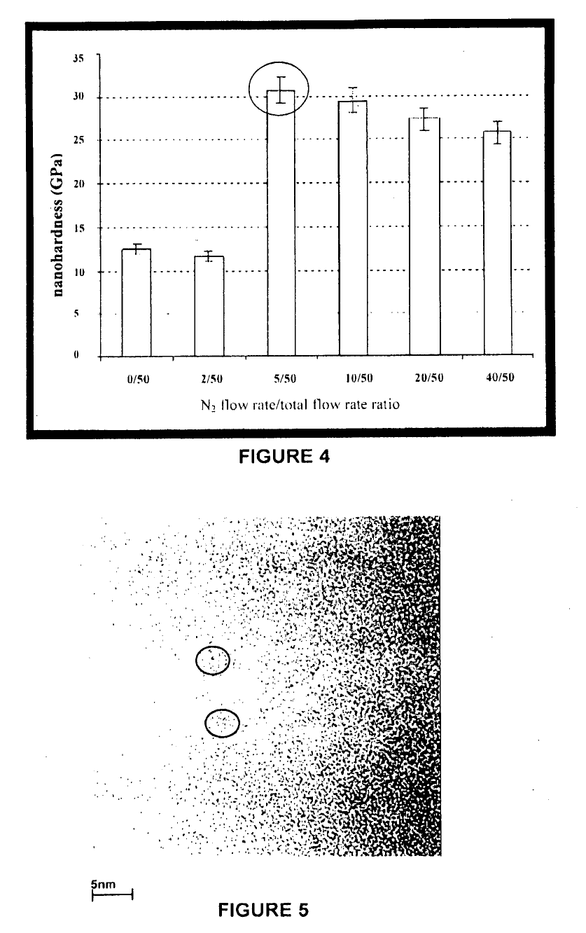

FIG. 4 represents the evolution of the hardness of the final coating film of the invention as a function of the nitrogen flow/total flow ratio of the gas mixture introduced into the magnetron cathodic sputtering chamber; and

FIG. 5 is a photograph obtained by high-resolution transmission electron microscopy of the nanocomposite structure of the final film of the coating obtained by the method of the invention. In this photograph, 1 cm represents 5 nanometres of the film shown.

The invention consists in depositing on a substrate made of a metal, a plastic or a ceramic having at least one surface with a polished mirror, a nanocomposite nanostructured coating based on Ti, Zr, B and N, having a hardness greater than 20 GPa for coating thicknesses less than or equal to 200 nm.

The thickness conventionally deposited in the prior art is around 2 to 3 micrometres for such coatings, i.e. 10 times more than the invention, to obtain hardness levels of around 30 GPa.

Obtaining extremely high hardness for such low deposition thicknesses, with low surface roughness, is made possible in the invention by developing a composite coating based on Ti, Zr, B and N, with a nanocomposite structure and a particular architecture.

The method of the invention is a magnetron cathode sputtering method in reactive co-sputtering mode in which, apart from the particular architecture of the coating, the ratio of the power applied to the sources of Ti on the one hand and of ZrB₂ on the other is controlled, nitrogen being introduced, also in a particular ratio, in gas form in a mixture with argon.

The magnetron cathode sputtering device in reactive co-sputtering mode is schematically represented in FIG. 1.

This device consists of a chamber, marked 1 in FIG. 1, comprising a gas inlet, marked 4 in FIG. 1. At the centre of the chamber a sample holder, marked 5 in FIG. 1, is located, on which the sample is placed, marked 6 in FIG. 1, at least one surface of which is to be coated.

Two targets, one made of ZrB₂ marked 2 in FIG. 1, and the other made of titanium marked 3 in FIG. 1, are positioned symmetrically in relation to the axis of symmetry of the sample holder 5, and facing it, each forming an angle of 60° relative to the axis of symmetry of the sample holder 5.

The distance between the centre of the sample 6 and the surface of the targets 2, 3 is 70 mm.

The sample 6 is centred on the sample holder 5 so as to have the same distance between the sample 6 and the two targets 2, 3.

Next, a power is applied to one and/or the other of the targets 2, 3, which causes an ionization of the material of the target which is deposited on the bare surfaces of the sample 6.

Thus, through this method, very thin coatings are obtained with low surface roughness. The material obtained is a nanocomposite material with a composition based on Ti, Zr, B and N, well known for having high hardness properties.

In order to optimize the adherence of this deposit on the sample, due to the low ionization rate obtained with the magnetron cathode sputtering method, a particular coating architecture must be complied with. This architecture is shown in FIG. 2.

As seen in FIG. 2, in the method of the invention a first film, marked 7 in FIG. 2, of Ti is deposited on the surface to be coated of the sample 6, on which film 7 another film, marked 8 in FIG. 2, of TiN is deposited, before proceeding to deposit the film, marked 9 in FIG. 2, of nanostructured material itself.

The composition of the film 9 based on Ti, Zr, B and N is obtained in the invention by applying a power ratio X/Y, in which X represents the power applied to the ZrB₂ target 2 and Y represents the power applied to the titanium target 3, included in the interval between 3/5 and 5/3 inclusive, preferably with a ratio of 1, as seen in FIG. 3.

Indeed, FIG. 3 represents the atomic composition in Ti and in Zr, along with the hardness measured by nanoindentation of the films developed at various X/Y power ratios applied to the sputtering targets 2, 3.

In FIG. 3, the x-axis represents the ratios of the powers expressed in watts. In other words, when a ratio of 100/500 is indicated on the x-axis, this means that a power of 100 W has been applied to the ZrB₂ target 2 and that a power of 500 W has been applied at the same time to the titanium target 3. In FIG. 3, the left y-coordinate represents the composition, in atomic percentage, of the coating obtained: the curve marked 10 in FIG. 3 represents the development of the atomic percentage of zirconium in the film 9 obtained, and the curve marked 11 in FIG. 3 represents the development of the atomic percentage of titanium in the film 9 obtained, according to the ratio X/Y of the powers applied to the ZrB₂ and Ti targets 2, 3.

The right y-coordinate in FIG. 3 represents the scale of nanohardness in GPa of the films obtained according to the powers applied. These hardness values are represented in the form of bars in FIG. 3.

Thus in FIG. 3 it is seen that films with a hardness greater than 20 GPa are obtained when power ratios X/Y between 3/5 and 5/3 inclusive are applied.

The hardness is measured by nanoindentation through the method described in Nanoindentation of Coatings, J. Phys. D.: Appl. Phys. 38 (2005) R393-R413.

But the X/Y power ratio parameter is not the only parameter of the method.

This is because to obtain the film 9 of the desired composition and hardness it is necessary to introduce nitrogen into the sputtering chamber.

This is done by introducing into the chamber a gas mixture consisting of argon and nitrogen containing at least 10% by volume of nitrogen in relation to the total volume of the argon+nitrogen mixture. This percentage enables a fully reactive sputtering system to be obtained, i.e. the targets are completely poisoned.

The optimum percentage of nitrogen in the mixture is 10%, as seen in FIG. 4.

FIG. 4 represents nanohardness, in GPa, of films developed from various percentages of nitrogen in the argon+nitrogen mixture. Hence, it is seen that a nitrogen percentage of 10% is optimal, but that beyond this nanohardness values of 20 GPa are also obtained.

The films according to the invention are deposited at ambient temperature.

In order to allow better understanding of the invention, an embodiment will now be described which is provided purely by way of illustration and is non-limiting.

### EXAMPLE 1

This example will be described with reference to FIGS. 1 and 2.

### a) Stripping of the Part to be Coated

The sample 6, one surface of which is to be coated, is a mirror-polished M2 high-speed-steel disc.

The sample 6 is placed on the sample holder 5 represented in FIG. 1, centred so as to have the same distance between the sample 6 and the targets 2 and 3, of ZrB₂ and Ti respectively.

First of all, the chamber 1 is subjected to a high vacuum of around 10⁻⁶ mbar.

The sample 6 is positioned so that it is not facing the sputtering targets 1 and 2.

The sputtering voltage of the sample is −500 V and the pressure in the chamber is a partial pressure of pure argon of 1 Pa. The argon is introduced through the gas inlet at a rate of 50 sccm. The duration of the stripping of the part is 4 minutes.

As the part is not positioned facing the targets, no coating is carried out.

### b) Deposition of the Titanium Film 7

Next the application of power to the ZrB₂ target 2 is stopped and the power applied to the titanium target 3 is fixed at 350 W, which corresponds, for the size of the titanium target 3 used here, to an applied power of 1.2 W/cm², still at a partial pressure of argon of 1 Pa.

The sample 6 is positioned facing the targets, i.e. centrally on the sample holder so that there is the same distance between the sample 6 and the two targets 2 and 3.

A bias voltage is applied to the sample progressively from −500 to −300 V.

This step corresponds to the step of deposition of the Ti film marked 7 in FIG. 2 onto the surface of the sample 6. The duration of this titanium deposition step is one minute. The thickness of the Ti film obtained is nm.

### c) Deposition of the TiN Film 8

The titanium nitride film, marked 8 in FIG. 2, is then deposited.

To do this, a mixture of argon and nitrogen is introduced as a reactive gas while conserving a pressure of 1 Pa in the chamber 1. The argon flow rate is 20 sccm and the nitrogen flow rate is 30 sccm. The duration of the deposition is 30 seconds. The film 8 obtained is a stoichiometric titanium nitride film. The thickness of the titanium nitride film 8 is 15 nm.

### d) Deposition of the Film 9 of Nanostructured Material

Next, the film 9 based on Ti, Zr, B and N is then deposited. To do this, the power applied to the ZrB₂ target 2 is increased from 0 to 350 W, which corresponds to a power applied to the target 2 of 1.2 W/cm², while keeping the power applied to the Ti target 3 at 350 W. The duration of the deposition is 6 minutes. The nitrogen flow rate is 5 sccm and the argon flow rate is 45 sccm, i.e. a percentage of nitrogen of 10% by volume in relation to the total gas volume.

The film 9 obtained by this method is a nanocomposite structure material based on titanium, zirconium, boron and nitrogen. The crystallites of this nanocomposite phase consist of titanium, zirconium and nitrogen, and the amorphous phase is of the boron nitride type, i.e. based on titanium, zirconium, boron and nitrogen.

It is a truly nanocomposite structure as shown in FIG. 5, which is a photograph obtained by high-resolution transmission electron microscopy of the film 9 obtained in this example. The size of the nanocrystals is around 4 nm and the roughness of each film is 4 nm. The roughness, Ra, is measured by profilometry using a mechanical stylus according to the ISO 4287 standard.

The thickness of this film 9 is 100 nm and its hardness is around 30 GPa as is seen in FIGS. 3 and 4.

There are multiple industrial applications of this type of coating, just as there are multiple fields in which hard coatings of hardness greater than 20 GPa must remain extremely thin, i.e. of a thickness less than or equal to 200 nm.

Thus, the first application of the method of the invention is the coating of razor blades in order to improve the resistance of the cutting edges of these blades to wear. Currently the surface hardness of a blade is 7 GPa. The hard films in this field may not exceed 100 nm in order to preserve a certain sharpness of the edge.

The second type of application is the protection against wear of micro-objects or MEMs. This is because this field is also confronted with problems of severe abrasive wear on parts in contact such as microgears.

The application of a hard film to this type of object is indispensable and must not affect the geometry of this object at the micrometre scale. In this case too, the possibility of combining a very hard and a very thin film represents a major benefit.

1. A method for forming a coating with a thickness less than or equal to 200 nm and a hardness greater than or equal to 20 GPa, and made of a material with a nanocomposite structure based on titanium, zirconium, boron and nitrogen, on a substrate, the method comprising:
a) depositing, by magnetron cathode sputtering, of a titanium film on at least one surface of a substrate under a partial pressure of argon of 1 Pa;
b) depositing, by magnetron cathode sputtering, a titanium nitride film, onto the film obtained in step a) by introducing nitrogen into the cathodic sputtering chamber while maintaining a partial pressure of 1 Pa;
c) depositing of a film a composite nanostructured material based on titanium, zirconium, boron and nitrogen onto the film obtained in step b) by magnetron cathode sputtering in active co-sputtering mode by applying a power X to a target source of titanium and a power Y to a target source of ZrB₂, the ratio X/Y being between 3/5 and 5/3 inclusive, and simultaneously injecting a gas mixture composed of argon and nitrogen, the nitrogen representing at least 10% by volume of the total volume of the gas mixture, while maintaining a partial pressure of 1 Pa and applying a bias voltage of −300 V in the cathodic sputtering chamber.

2. A method according to claim 1, characterized in that in step c) the nitrogen represents 10% by volume of the total volume of the gas mixture.

3. A method according to claim 1, characterized in that in step c) the ratio X/Y=1.

4. A device comprising a coating obtained by the method of claim 1.

5. A device according to claim 4 comprising a razor blade.
